(19) United States
(12) Patent Application Publication
(10) Pub. No.: US 2025/0210379 A1
(43) Pub. Date: Jun. 26, 2025

(54) SUBSTRATE TREATING APPARATUS AND SUBSTRATE TREATING METHOD

(71) Applicant: SEMES CO., LTD., Cheonan-si (KR)

(72) Inventors: Gu Won SEON, Seoul (KR); Jin Kyu KIM, Suwon-si (KR); Jae Seung YU, Seoul (KR); Hee Man AHN, Seoul (KR); Sung Hun EOM, Hwaseong-si (KR); Gyeong Won SONG, Cheonan-si (KR)

(73) Assignee: SEMES CO., LTD., Cheonan-si (KR)

(21) Appl. No.: 18/968,179

(22) Filed: Dec. 4, 2024

(30) Foreign Application Priority Data
Dec. 26, 2023 (KR) 10-2023-0191246

(51) Int. Cl. H01L 21/67

(52) U.S. Cl. CPC H01L 21/67034; H01L 21/67051

(57) ABSTRACT

Disclosed is a substrate treating apparatus for treating a substrate, the substrate treating apparatus including: a cup for providing a treatment space; a support unit provided to support a substrate in the treatment space; a cleaning solution supply unit for supplying a cleaning solution to the substrate supported on the support unit; and a controller for controlling the support unit and the cleaning solution supply unit, in which the cleaning solution supply unit includes: a support arm; a discharge head provided with a plurality of nozzles having outlets of different sizes; a rotating unit for rotating the discharge head; and a moving unit for moving the discharge head between a center region of the substrate and an edge region of the substrate, and the controller causes the cleaning solution to be discharged while moving the discharge head between a center region of the substrate and an edge region of the substrate, and rotates the rotating unit such that, upon movement of the discharge head, nozzles having smaller inner diameters of the outlet are placed from the center region of the substrate to the edge region.

### CROSS-REFERENCE TO RELATED APPLICATIONS

This application claims priority to and the benefit of Korean Patent Application No. 10-2023-0191246 filed in the Korean Intellectual Property Office on Dec. 26, 2023, the entire contents of which are incorporated herein by reference.

### TECHNICAL FIELD

The present invention relates to a substrate treating apparatus and a substrate treating method that treat a substrate.

### BACKGROUND ART

To manufacture semiconductor devices or flat display panels, various processes, such as deposition, photography, etching, and cleaning, are performed. Among these processes, the photography process includes an application process in which a photosensitive liquid, such as a photoresist, is applied to a surface of a substrate to form a film, an exposure process in which a circuit pattern is transferred to the film formed on the substrate, and a development process in which the film formed on the substrate is selectively removed from the exposed region or an opposite region of the exposed region. Further, a heat treatment process is performed before and after the application process, the exposure process, and the development process.

On the other hand, during the development process, a developer is poured onto the entire exposed photosensitizer to develop the photosensitizer, and then the developed photosensitizer is cleaned with a cleaning solution.

In this case, the cleaning solution is disposed on a rotating substrate, and the cleaning solution is discharged through the nozzle to a top surface of the rotating substrate. In this case, the linear velocity of the substrate increases from the center to the edge when rotating. In this case, when the discharge velocity of the cleaning solution is different from the linear velocity of the substrate, the cleaning solution bounces back at the moment the cleaning solution touches the rotating substrate, causing a scattering phenomenon.

However, since the conventional cleaning solution is discharged at a set velocity from a single nozzle, splashing phenomenon inevitably occurs in the section where the difference between the discharge velocity and the linear velocity is large. In particular, the edge region of the substrate has a larger linear velocity than the center, so the more scattering phenomenon occurs toward the edge.

As a result, the above-mentioned scattering phenomenon causes the nozzle to become contaminated with developing residue of the substrate around the nozzle, and eventually the contaminated nozzle discharges the developing residue along with the cleaning solution onto the substrate, causing substrate fault.

### SUMMARY OF THE INVENTION

The present invention has been made in an effort to provide a substrate treating apparatus and a substrate treating method that are capable of minimizing liquid scattering by minimizing a difference between a linear velocity of a substrate and a liquid discharge velocity when discharging a liquid onto a substrate having a different linear velocity from a center to an edge.

The problem to be solved by the present invention is not limited to the above-mentioned problems, and the problems not mentioned will be clearly understood by those skilled in the art from the descriptions below.

An exemplary embodiment of the present invention provides a substrate treating apparatus for treating a substrate, the substrate treating apparatus including: a cup for providing a treatment space; a support unit provided to support a substrate in the treatment space; a cleaning solution supply unit for supplying a cleaning solution to the substrate supported on the support unit; and a controller for controlling the support unit and the cleaning solution supply unit, in which the cleaning solution supply unit includes: a support arm; a discharge head provided with a plurality of nozzles having outlets of different sizes; a rotating unit for rotating the discharge head; and a moving unit for moving the discharge head between a center region of the substrate and an edge region of the substrate, and the controller causes the cleaning solution to be discharged while moving the discharge head between a center region of the substrate and an edge region of the substrate, and rotates the rotating unit such that, upon movement of the discharge head, nozzles having smaller inner diameters of the outlet are placed from the center region of the substrate to the edge region.

According to the exemplary embodiment, the cleaning solution supply unit may further include a connecting rod coupling the discharge head to the support arm, and the rotating unit may rotate the discharge head about a center axis of the connecting rod.

According to the exemplary embodiment, the plurality of nozzles may be arranged in a direction surrounding a center of the discharge head.

According to the exemplary embodiment, the plurality of nozzles may be disposed at equal distances from each other from the center of the discharge head.

According to the exemplary embodiment, the plurality of nozzles may be arranged such that the size of the outlet increases progressively in a direction of rotation in one direction relative to the center of the discharge head.

According to the exemplary embodiment, the cleaning solution supply unit may further include a drying gas nozzle coupled to the support arm and discharging drying gas onto the substrate.

According to the exemplary embodiment, the cleaning solution supply unit may further include: a tilting unit for tilting the discharge head such that an angle of discharge of the cleaning solution is downwardly directed toward a deposit point of drying gas discharged from the drying gas nozzle.

According to the exemplary embodiment, said controller may control said tilting unit such that a tilting angle of said discharge head varies according to the inner diameter of said nozzle.

According to the exemplary embodiment, the cleaning solution supply unit may further include a discharge direction changer, which is coupled to at least one of the plurality of nozzles and changes the direction of discharging the cleaning solution to face a direction different from the other plurality of nozzles.

According to the exemplary embodiment, he cleaning solution supply unit may further include: a liquid supply line for receiving the cleaning solution from a cleaning solution supply source; a plurality of branch lines having one end connected to the liquid supply line and the other end connected to each of the plurality of nozzles; and an opening and closing valve installed in each of the branch lines and allowing or blocking flow of the cleaning solution into the branch lines.

According to the exemplary embodiment, the branch line may have at least a portion made of a soft material.

Another exemplary embodiment of the present invention provides a substrate treating method of treating a substrate, the substrate treating method including: a substrate seating operation for seating a substrate to a support unit; a substrate rotating operation of rotating the substrate seated on the support unit; and a liquid discharging operation of discharging a liquid onto a top surface of the substrate from a plurality of nozzles while moving a discharge head equipped with the plurality of nozzles having outlets with different sizes in a direction from a center of the substrate toward an edge region of the substrate, wherein the cleaning solution is discharged from nozzles that have larger inner diameters of the outlets as being closer to the center of the substrate and the cleaning solution is discharged from nozzles that have smaller inner diameters of the outlets as being closer to the edge region of the substrate.

According to the exemplary embodiment, during the liquid discharging operation, the discharge head may swing or linearly move, and a point of deposit of the cleaning solution on the substrate may be moved along a straight line or an arc trajectory.

According to the exemplary embodiment, the liquid discharging operation may include discharging the cleaning solution from only one nozzle selected from the plurality of nozzles, and changing a nozzle discharging the cleaning solution while the discharge head is being moved in the liquid discharging operation.

According to the exemplary embodiment, the change of the nozzle may be accomplished by rotating the discharge head about a center axis of the discharge head.

According to the exemplary embodiment, during the liquid discharging operation, drying gas may be discharged onto the substrate and the cleaning solution may be discharged with a downward inclination toward a point where the drying gas is deposited onto the substrate.

According to the exemplary embodiment, the liquid discharging operation may include changing an angle of discharging of the cleaning solution by tilting the discharge head.

In the liquid discharging operation, a tilting angle of the discharge head may be adjusted differently according to an inner diameter of the nozzle.

According to the exemplary embodiment, the liquid discharging operation may include adjusting an angle of the nozzle such that a direction of discharging the cleaning solution of at least one of the plurality of nozzles faces a direction different from the other plurality of nozzles.

Still another exemplary embodiment of the present invention provides an apparatus for treating a substrate, the apparatus including: a cup for providing a treatment space; a support unit provided to support a substrate in the treatment space; a cleaning solution supply unit for supplying a cleaning solution to the substrate supported on the support unit; and a controller for controlling the support unit and the cleaning solution supply unit, in which the cleaning solution supply unit further includes: a discharge head provided with a plurality of nozzles having outlets with different sizes; a rotating unit for rotating the discharge head about a center axis of a connecting rod; and a moving unit for moving the discharge head between a center region of the substrate and an edge region of the substrate, the plurality of nozzles is arranged in a direction surrounding a center of the discharge head, the plurality of nozzles is disposed at equal distances from each other from the center of the discharge head, and the controller controls the cleaning solution supply unit to discharge the cleaning solution in a moving line during movement of the discharge head, wherein the controller controls the cleaning solution to be supplied from one nozzle selected from the plurality of nozzles, and the controller controls the cleaning solution supply unit to change a nozzle discharging the cleaning solution among the plurality of nozzles during the movement of the discharge head.

The present invention has the effect of minimizing the scattering of a liquid by minimizing a difference between a linear velocity of a substrate and a liquid discharge velocity when the liquid is discharged onto the substrate having different linear velocities from a center to an edge.

The effect of the present invention is not limited to the foregoing effects, and non-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate treating apparatus according to an exemplary embodiment of the present invention.

FIG. 2 is a cross-sectional view of the substrate treating apparatus of FIG. 1.

FIG. 3 is a front view schematically illustrating a liquid treating chamber provided in a developing block.

FIG. 4 is an enlarged, schematic side view of a cleaning solution supply unit illustrated in FIG. 3.

FIG. 5 is a perspective view of a discharge head illustrated in FIG. 4.

FIG. 6 is a bottom view of the discharge head illustrated in FIG. 5.

FIG. 7 is a bottom view of the discharge head illustrated in FIG. 6 in a state where the discharge head is rotated.

FIG. 8 is a line schematic diagram of the liquid supplied to the nozzle illustrated in FIG. 3.

FIG. 9 is a side view in a state where the discharge head illustrated in FIG. 4 is tilted.

FIG. 10 is a partial side view in a state where a discharge angle for any of the nozzles illustrated in FIG. 4 is changed.

FIG. 11 is a flowchart of a substrate treating method according to an exemplary embodiment of the present invention.

FIGS. 12 to 14 are driving diagrams of the substrate treating apparatus according to a substrate treating method according to the exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be processed. However, the technical spirit of the present invention may be applied to devices used for other types of substrate treatment, in addition to wafers.

Hereinafter, exemplary embodiments of the present invention will be described with reference to the accompanying drawings.

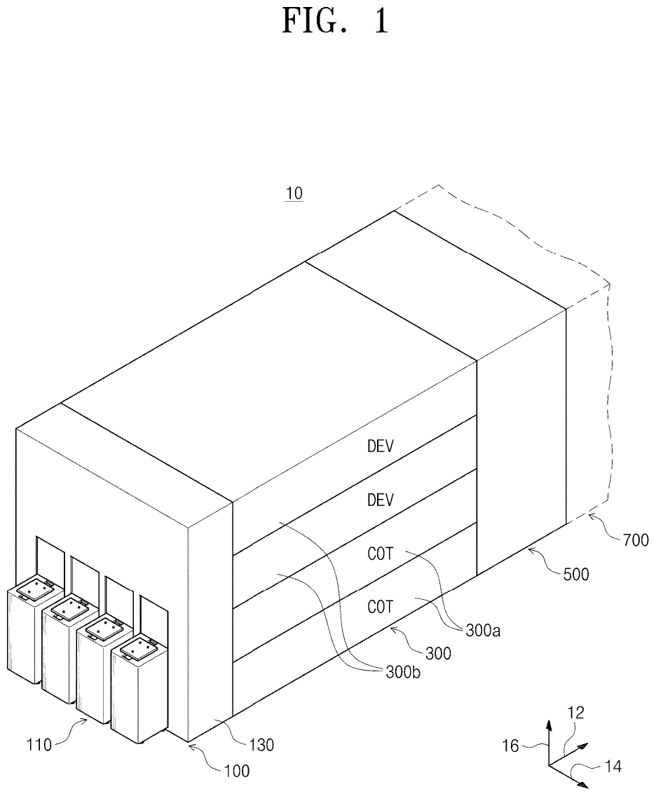

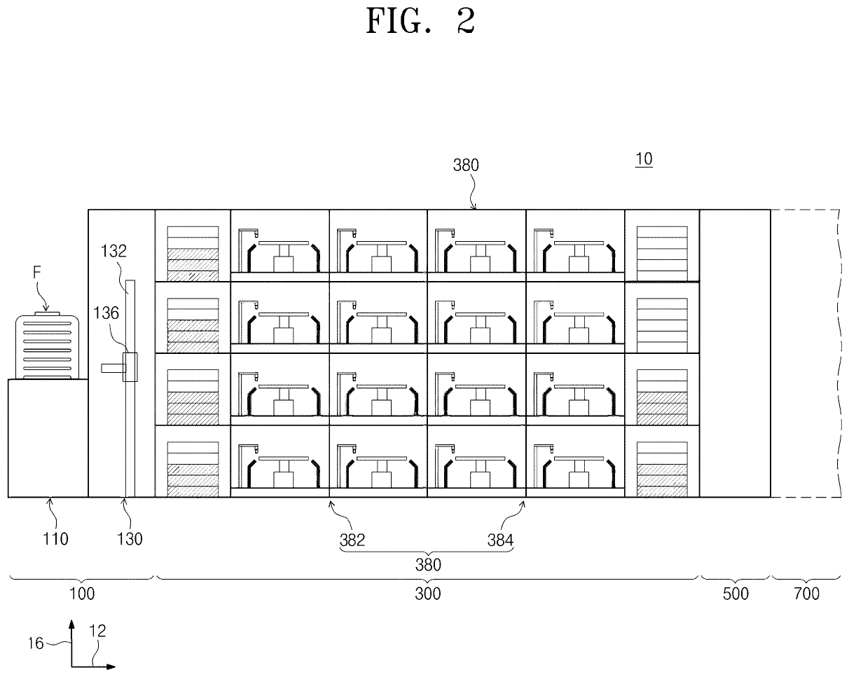

FIG. 1 is a perspective view schematically illustrating a substrate treating apparatus according to an exemplary embodiment of the present invention, and FIG. 2 is a cross-sectional view of the substrate treating apparatus of FIG. 1.

Referring to FIGS. 1 and 2, a substrate treating apparatus 10 includes an index module 100, a treating module 300, and an interface module 500. According to the exemplary embodiment, the index module 100, the treating module 300, and the interface module 500 are sequentially arranged in a row. Hereinafter, a direction in which the index module 100, the treating module 300, and the interface module 500 are arranged is defined as a first direction 12, a direction perpendicular to the first direction 12 when viewed from above is defined as a second direction 14, and a direction perpendicular to both the first direction 12 and the second direction 14 is defined as a third direction 16.

The index module 100 is provided for transferring a substrate W between a container F in which the substrate W is accommodated and the treating module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the treating module 300 with respect to the index frame 130. A plurality of load ports 110 may be provided, and the plurality of load ports 110 may be disposed along the second direction 14.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forwardly and backwardly, movable linearly along the third direction, and rotatably movable about the axis of the third direction 16.

The treating module 300 performs an application process and a development process on the substrate W. The treating module 300 includes an applying block 300a and a developing block 300b.

The applying block 300a performs an application process on the substrate W before the exposure process. A plurality of applying blocks 300a is provided. The plurality of applying blocks 300a may be provided while being stacked on top of each other. In one example, two applying blocks 300a are provided and two developing blocks 300b are provided. The plurality of applying blocks 300a may be located below the developing blocks 300b.

Additionally, the applying block 300a may include a liquid treating chamber 380.

The liquid treating chamber 380 provided in the applying block 300a performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process.

A plurality of liquid treating chambers 380 is provided. The liquid treating chambers 380 may be located on opposite sides of the heat treating chamber 360. For example, all of the liquid treating chambers 380 may be located on the other side of the transfer chamber 350. The liquid treating chambers 380 are arranged side-by-side along the first direction 12. Optionally, some of the liquid treating chambers 360 may be stacked along the third direction 16.

In one example, the liquid treating chambers 380 include a front end liquid treating chamber 380a and a rear end liquid treating chamber 380b. The front end liquid treating chamber 380a is disposed relatively close to the index module 100, and the rear end liquid treating chamber 380b is disposed further close to the interface module 500.

The front end liquid treating chamber 380a applies a first liquid to the substrate W, and the rear end liquid treating chamber 380b applies a second liquid to the substrate W. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film, and the second liquid may be a liquid for forming an antireflective film. In this case, the anti-reflective film may be formed on the substrate W on which the photoresist film is formed. Optionally, the first liquid and the second liquid may be the same kind of liquid, and they may both be liquids for forming the photoresist film.

The developing block 300b performs a development process on the substrate W after the exposure process. A plurality of developing blocks 300b is provided. The plurality of developing blocks 300b may be provided to be stacked with each other. The plurality of developing blocks 300b may be provided in the same structure. A developer supplied to the substrate W in the plurality of developing blocks 300b may be the same type of liquid. Optionally, the developer supplied to the substrate W may be different types of developer depending on the developing blocks 300b. For example, a process for removing a light-irradiated region in a region of a register film on the substrate W may be performed in one of the two developing blocks 300b, and a process for removing a non-irradiated region may be performed in the other of the two developing blocks 300b.

Further, the developing block 300b may include the liquid treating chamber 380.

The liquid treating chamber 380 provided to the developing block 300b performs a developing process of developing the substrate W by supplying a developer onto the substrate W.

The interface module 500 connects the treating module 300 with an external exposing device 700. The interface module 500 may load and unload the substrate W to and from the exposing device 700, and perform additional processes.

The exposing device 700 exposes the substrate W to which the film is applied by the applying block 300a. The exposing device 700 discharges the exposed substrate W via the interface module 500 to the developing block 300b.

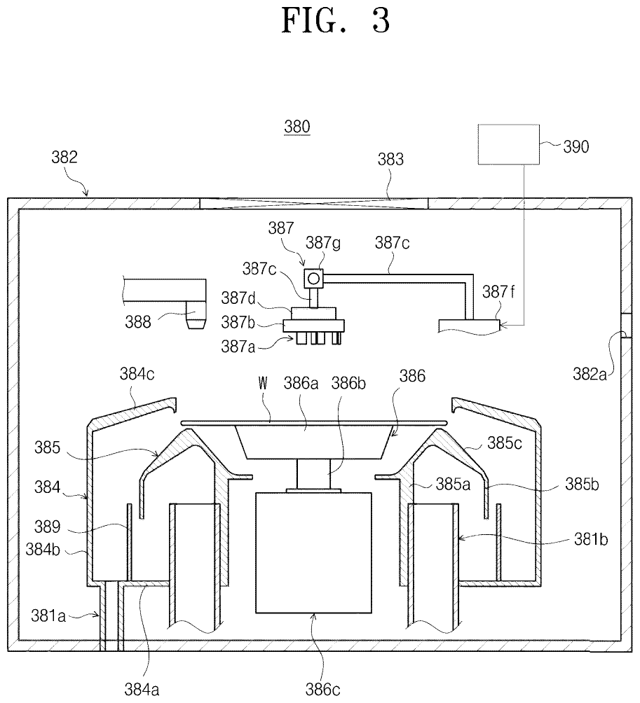

FIG. 3 is a front view schematically illustrating the liquid treating chamber provided in the developing block.

Referring further to FIG. 3, the liquid treating chamber 380 provided in the developing block 300b includes a housing 382, an outer cup 384, a support unit 386, and a cleaning solution supply unit 387.

The housing 382 is provided in a rectangular cylindrical shape having an interior space. An opening 382a is formed in one side of the housing 382. The opening 382a functions as a passage through which the substrate W enters and exits. A door (not illustrated) is installed in the opening 382a, and the door opens and closes the opening.

An interior space of the housing 382 is provided with the outer cup 384. The outer cup 384 has a treatment space with an open top.

The support unit 386 supports the substrate W within the treatment space of the outer cup 384. The support unit 386 includes has a support plate 386a, a rotation shaft 386b, and a driver 386c. The support plate 386a is provided with a circular top surface. The support plate 386a has a diameter smaller than the substrate W. The support plate 386a is provided to support the substrate W by vacuum pressure. The rotation shaft 386b is coupled to the center of the lower surface of the support plate 386a, and the driver 386c is provided on the rotation shaft 386b to provide rotational force to the rotation shaft 386b. The driver 386c may be a motor. Additionally, a lifting driver (not illustrated) may be provided to adjust the relative height of the support plate 386a and the outer cup 384.

The treatment solution supply unit 388 supplies the treatment solution to the substrate W. When the liquid treating chamber 380 is provided in the applying block 300a, the treatment solution may be a liquid for forming a photoresist film, an anti-reflective film, or a protective film. When the liquid treating chamber 380 is provided in the developing block 300b, the treatment solution may be a developer liquid.

The cleaning solution supply unit 387 supplies a cleaning solution to the substrate W. In one example, the cleaning solution may be pure water. The cleaning solution supply unit 387 will be described in more detail below with further reference to the drawings.

On the top wall of the housing 382, a fan filter unit 383 is disposed to supply a downward airflow to the interior space. The fan filter unit 383 includes a fan that introduces air from the outside into the interior space and a filter that filters the air from the outside.

The outer cup 384 includes a bottom wall 384a, a lateral wall 384b, and a top wall 384c. The inner portion of the outer cup 384 is provided as the interior space described above. The interior space includes a treatment space at the top and an exhaust space at the bottom.

The bottom wall 384a is provided in a circular shape and has an opening in the center. The lateral wall 384b extends upwardly from the outer end of the bottom wall 384a. The lateral wall 384b is provided in a ring shape and is provided vertical to the bottom wall 384a. In one example, the lateral wall 384b extends to a height equal to the top surface of the support plate 386a, or extends to a height slightly lower than the top surface of the support plate 386a. The top wall 384c has a ring shape, with an opening in the center. The top wall 384c is provided with an upward slope from the top end of the lateral wall 384b toward the center axis of the outer cup 384.

The guide cup 385 is located on the inner side of the outer cup 384. The guide cup 385 has an inner wall 385a, an outer wall 385b, and a top wall 385c. The inner wall 385a has a through-hole that is perforated in the vertical direction. The inner wall 385a is arranged to surround the driver 386c. The inner wall 385a minimizes the exposure of the driver 386c to the airflow 84 in the treatment space. The rotational shaft 386b and/or the driver 386c of the support unit 386 extend in the vertical direction through the through-hole. The outer wall 385b is spaced apart from the inner wall 385a and is disposed to surround the inner wall 385a. The outer wall 385b is spaced apart from the lateral wall 384b of the outer cup 384. The inner wall 385a is spaced upwardly from the bottom wall 384a of the outer cup 384. The top wall 385c connects the upper end of the outer wall 385b with the upper end of the inner wall 385a. The top wall 385c has a ring shape and is disposed to surround the support plate 386a. In one example, the top wall 385c has an upwardly convex shape.

The space below the support plate 386a in the treatment space may be provided as an exhaust space. In one example, the exhaust space may be defined by the guide cup 385. The space surrounded by the outer wall 385b, the top wall 385c, and the inner wall 385a of the guide cup 385 and/or the space below the space may be provided as the exhaust space.

The outer cup 384 may be provided with a gas-liquid separation plate 389. The gas-liquid separation plate 389 may be provided to extend upwardly from the bottom wall 384a of the outer cup 384. The gas-liquid separation plate 1230 may be provided in a ring shape. The gas-liquid separation plate 389 may be located between the lateral wall 384b of the outer cup 384 and the outer wall 385b of the guide cup 385 when viewed from above. The top end of the gas-liquid separation plate 389 may be located lower than the bottom end of the outer wall 385b of the guide cup 385.

The bottom wall 384a of the outer cup 384 is connected to an outlet pipe 381a for discharging the treatment solution and an outlet pipe 381b. The outlet pipe 381a may be connected to the outer cup 384 from the outer side of the gas-liquid separation plate 389. The exhaust pipe 381b may be connected to the outer cup 384 from an inner side of the gas-liquid separation plate 389.

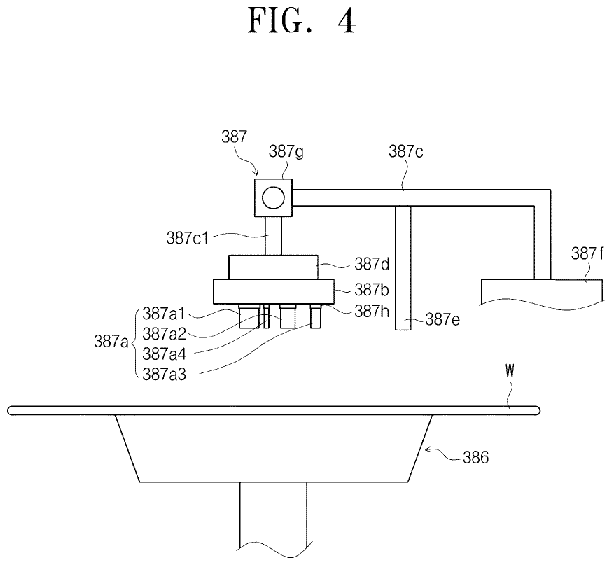

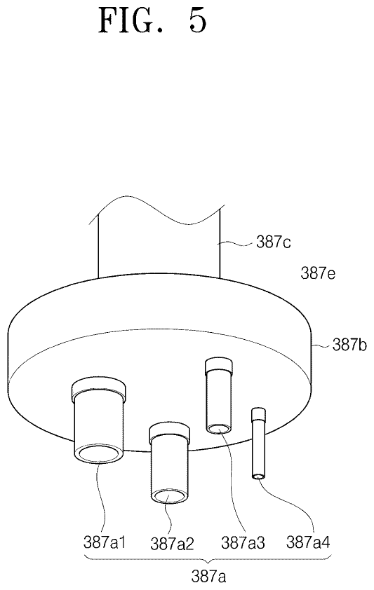

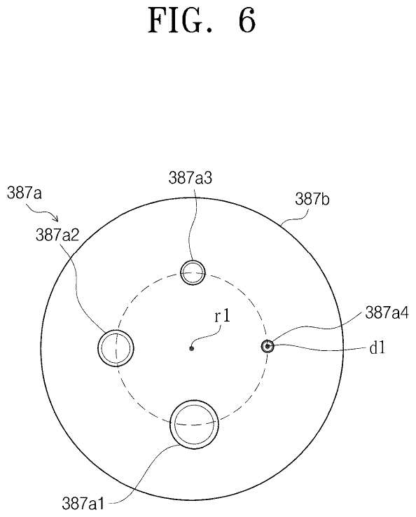

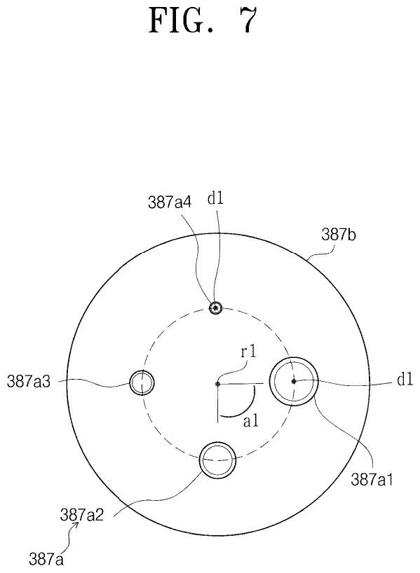

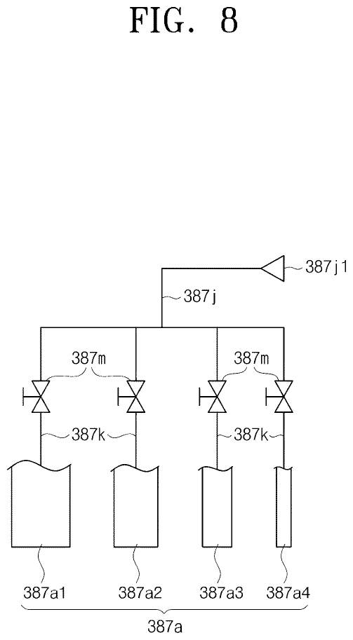

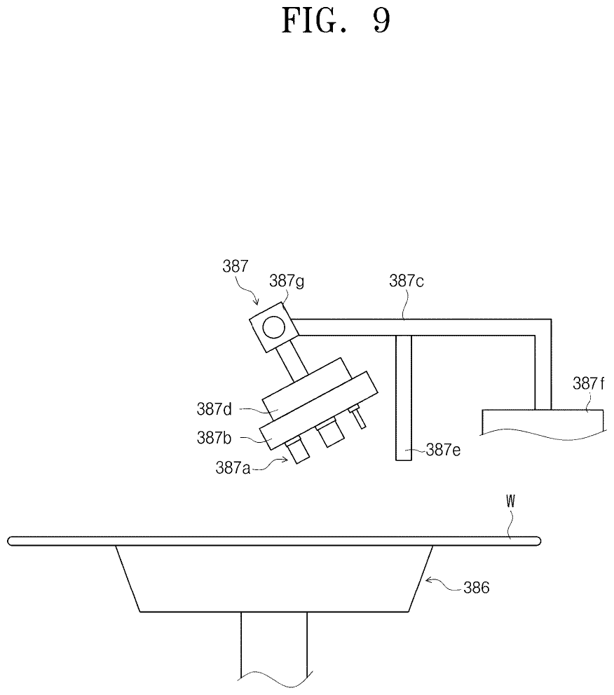

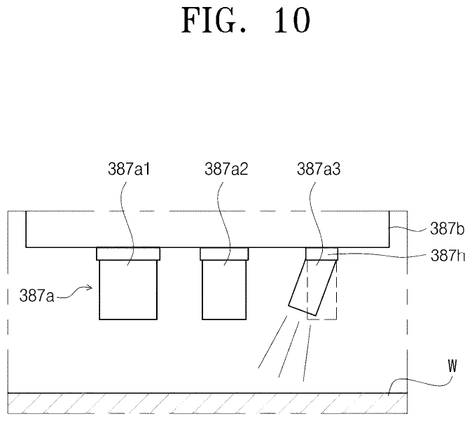

FIG. 4 is an enlarged, schematic lateral view of the cleaning solution supply unit illustrated in FIG. 3. FIG. 5 is a perspective view of a discharge head illustrated in FIG. 4. FIG. 6 is a bottom view of the discharge head illustrated in FIG. 5. FIG. 7 is a bottom view of the discharge head illustrated in FIG. 6 in a state where the discharge head is rotated. FIG. 8 is a line schematic diagram of the liquid supplied to the nozzle illustrated in FIG. 3. FIG. 9 is a side view in a state where the discharge head illustrated in FIG. 4 is tilted. FIG. 10 is a partial side view in a state where a discharge angle for any of the nozzles illustrated in FIG. 4 is changed.

Referring further to FIGS. 4 to 10, the cleaning solution supply unit 387 may include a nozzle 387a.

The nozzle 387a is schematically formed as a cylindrical tubular shape and is provided in a plurality. Each of the nozzles 387a discharges a liquid. Here, the liquid may be a cleaning solution that removes the film formed on the substrate W. For example, the cleaning solution may be pure water.

Additionally, the nozzles 387a may be configured to discharge a liquid from only one of the nozzles 387a. In this case, the nozzle 387a may be set to discharge a liquid at a discharge position d1, and the liquid discharged from the discharge position d1 may be discharged or stopped by a control operation of an opening and closing valve 387m described later.

Additionally, the nozzles 387a may be formed with different outlet sizes from one another. In this case, the outlet diameter of the nozzle 387a may selectively be configured within 0.7 mm to 8 mm. Accordingly, when each of the nozzles 387a is supplied with a liquid at the same flow rate, the nozzle 387a with the smaller diameter may discharge a liquid at the fastest flow rate and the nozzle 387a with the largest diameter may discharge a liquid at the slowest flow rate. For example, the nozzles 387a may include a first nozzle 387a1, a second nozzle 387a2, a third nozzle 387a3, and a fourth nozzle 387a4 that are spaced apart from each other, and in this case, the first nozzle 387a1, the second nozzle 387a2, the third nozzle 387a3, and the fourth nozzle 387a4 may be configured such that the size of the outlets decreases from the first nozzle 387a1 to the fourth nozzle 387a4. For example, an inner diameter of the outlet of the first nozzle 387a1 may be formed to be 8 mm, an inner diameter of the outlet of the second nozzle 387a2 may be formed to be 6 mm, an inner diameter of the outlet of the third nozzle 387a3 may be formed to be 3 mm, and an inner diameter of the outlet of the fourth nozzle 387a4 may be formed to be 1 mm.

In this case, the substrate W is rotated at a velocity predetermined by the rotation of the support unit 386. Accordingly, the angular velocity of the substrate W increases from the center to the farthest edge, so that the linear velocity increases from the center to the farthest edge. In this case, when the discharge velocity of the liquid discharged onto the substrate W is significantly different from the linear velocity of the substrate W, the liquid may be scattered and contaminate the region around the nozzle 387a. For example, when the velocity difference between the linear velocity of the substrate W and the velocity of the liquid discharged from the nozzle 387a is equal to or greater than 25 m/s, the liquid discharged onto the substrate W may splash back and contaminate the nozzle 387a due to the velocity difference.

Thus, in the present exemplary embodiment, the nozzles 387a may be set such that as the inner diameter of the outlet is smaller, the discharge position d1 for discharging a liquid is closer to the edge of the substrate W, and the inner diameter of the outlet is larger, the discharge position d1 for discharging liquid is closer to the center of the substrate W. Accordingly, when each of the nozzles 387a is supplied with the same flow rate, the nozzle 387a located closest to the edge of the substrate W supplies a liquid at the fastest flow rate, and the nozzle 387a located closest to the center of the substrate W supplies a liquid at the slowest flow rate. Therefore, near the edge of the substrate W where the linear velocity is fast, the nozzle 387a having the outlet with a relatively small inner diameter discharges a liquid at a fast flow rate to prevent scattering of the liquid, and near the center of the substrate W where the linear velocity is slow, the nozzle 387a having the outlet with a relatively large inner diameter discharges a liquid at a slow flow rate to prevent scattering.

In addition, the cleaning solution supply unit 387 may further include a discharge head 387b.

The discharge head 387b is schematically formed as a block shape. The discharge head 387b may be formed with a plurality of holes, and in this case, the nozzles 387a may be inserted and coupled to the plurality of holes.

Additionally, the nozzles 387a may be removably coupled to the discharge head 387b. In this case, the lower ends of the nozzles 387a may be positioned lower than the lower surface of the discharge head 387b. As such, the nozzles 387a may be removably coupled with the discharge head 387b to facilitate replacement, thereby facilitating coupling of the nozzles 387a with an inner diameter having a discharge velocity that is not significantly different from the linear velocity of the substrate W. In this case, the nozzles 387a may be arranged in such a way that they surround the center of the discharge head 387b.

Further, the cleaning solution supply unit 387 may further comprise a support arm 387c.

The support arm 387c may be schematically formed as a rod shape. In this case, the support arms 387c may be formed in plurality, each of which may be coupled to form an angle with respect to the other. For example, the support arm 387c may be formed with both ends bent at a certain angle, as illustrated in the drawing. Further, the support arm 387c may have one end connected with a connecting rod 387c1. The connecting rod 387c1 may be coupled to a rotating unit 387d. Furthermore, the support arm 387c may be coupled at the other end with a moving unit 387f. The support arm 387c may extend such that the discharge head 387b may be positioned not only in the space above the substrate W but also to the exterior side of the substrate W.

Further, the cleaning solution supply unit 387 may further include the rotating unit 387d. The rotating unit 387d may be connected between the discharge head 387b and the connecting rod 387c1. In one example, the rotating unit 387d may include a rotary actuator. As such, the rotating unit 387d may be rotatable relative to a center r1 of the discharge head 387b when viewed from above. In this case, the rotating unit 387d may be rotated at a preset angle a1 by a preset driving algorithm of the controller 390. In this case, each of the nozzles 387A may rotate circularly about the center r1 of the discharge head 387b, thereby designating the discharge position d1 of each of the nozzles 387A for each set angle a1. As a result, the nozzles 387a may always discharge the cleaning solution at the designated discharge position d1 without any teaching process, thus eliminating the need for careful management, and only the driving of rotating the discharge head 387b is required even when the discharge position d1 is changed, so that the control operation is advantageously very simple.

Here, the rotating unit 387d may move any one of the nozzles 387a to the discharge position where the liquid is discharged when the discharge head 387b is rotated by one angle, and move the other nozzles 387a to a standby position where the liquid is not discharged.

Further, the cleaning solution supply unit 387 may further include a drying gas nozzle 387e.

The drying gas nozzle 387e is schematically formed as a cylindrical tubular shape. The drying gas nozzle 387e may be coupled to the support arm 387c. The drying gas nozzle 387e is connected at one end to a drying gas supply source (not illustrated) by a line (not illustrated) to receive a supply of drying gas. As one example of the drying gas, the drying gas may be nitrogen gas. The drying gas nozzle 387e may discharge drying gas when discharging the cleaning solution from the nozzle 387a to blow one point of the substrate W, thereby drying the cleaning solution and increasing the removal rate of the film residue generated during development.

Further, the cleaning solution supply unit 387 may further include the moving unit 387f.

The moving unit 387f may be coupled to an end of the support arm 387c to which the discharge head 387b is coupled. Accordingly, the nozzle 387a may be coupled to the moving unit 387f. As one example of the moving unit 387f, the moving unit 387f may be a two-axis actuator for moving or a two-axis transfer robot that moves in a space parallel to the top surface of the substrate W. Such the moving unit 387f may move the position of the nozzle 387a in a plane parallel to the top surface of the substrate W. Thus, the nozzle 387a may be adjusted in the discharge position D1 by the moving unit 387f. In this case, the moving unit 387f may move the nozzle 387a discharging the liquid along a line. Furthermore, the moving unit 387f may move the nozzle 387a so that the nozzle 387a is not disposed in the upper space of the substrate W when the substrate W is being transferred, so that interference between the substrate W and the hand of the transfer robot 351 does not occur when the transfer robot 351 transfers the substrate W.

Further, the cleaning solution supply unit 387 may further include a tilting unit 387g.

The tilting unit 387g may be schematically formed of an actuator for tilting. The tilting unit 387g may be coupled to one point on the support arm 387c. In this case, the support arm 387c may be formed in plurality, and the tilting unit 387g may be coupled at one point where the plurality of support arms 387c meets one another. The tilting unit 387g may tilt the discharge head 387b to adjust the discharge angle of the cleaning solution. Thus, the nozzle 387a may discharge the liquid not only in a direction perpendicular to the top surface of the substrate W, but also in a direction diagonal to the top surface of the substrate W, since the discharge angle is adjusted by the tilting unit 387g when discharging the liquid. Thus, the nozzle 387a may discharge the liquid to be inclined downwardly toward a point where the drying gas is deposited upon when discharging the liquid. In this case, the controller 390 may control the tilting unit 387g such that the tilting angle of the discharge head 387b varies according to the inner diameter of the outlet of the nozzle 387a. Thus, the nozzles 387a having different inner diameters of the outlets may be adjusted to have different angles when discharging the liquid, so that the liquid may be discharged toward a point where the drying gas is deposited or toward a region spaced a certain distance from the point where the drying gas is deposited.

In addition, the cleaning solution supply unit 387 may further include a discharge direction changer 387h.

The discharge direction changer 387h may be coupled between at least one of the nozzles 387a and the discharge head 387b. In one example, the discharge direction changer 387h may be formed as a cylindrically shaped tube with a portion of the body bent. Such the discharge direction changer 387h may change the discharge direction such that the direction in which the liquid is discharged faces in a direction different from the other nozzles 387a. Thus, the discharge direction changer 387h may change the discharge direction such that liquid is discharged from the center to the edge of the substrate W. In particular, the discharge direction changer 387h may change the direction so that the liquid discharged overlaps the point where the drying gas meets the substrate W.

In addition, the cleaning solution supply unit 387 may further include a liquid supply line 387j, a branch line 387k, and an opening and closing valve 387m.

The liquid supply line 387j is connected to the liquid supply source 387j1 supplying the liquid to receive the liquid, and the received liquid is discharged to the branch line 387k. The liquid supply line 387j may further include a flow rate regulator (not illustrated) to regulate the flow rate of the liquid. When the liquid supply line 387j supplies the liquid to the branch line 387k, the liquid supply line 387j discharges the liquid so that the same flow rate flows through each of the branch lines 387k, and in this case, each of the nozzles 387a may regulate the flow rate and the discharge velocity according to the size of the inner diameter of the outlet without a configuration to separately adjust the discharge velocity.

The branch lines 387k may be formed in plurality. One end of each of the branch lines 387k is connected to the liquid supply line 387j to receive a liquid, and the other end of each of the branch lines 387k is connected to each of the nozzles 387a. In this case, the branch line 387k may have at least a portion of the body formed of a soft material. In one example, the branch line 387k may be formed of a tube of a resinous material having high corrosion resistance and heat resistance. Thus, the branch line 387k may flexibly bend even when the nozzle 387a is rotated by the tilting unit 387g, so that the liquid may be easily supplied to the nozzle 387a side without the liquid being blocked by a kinking phenomenon.

The opening and closing valves 387m may be formed in plurality, each of which is installed on each of the branch lines 387k. In one example, the opening and closing valves 387m may be configured as solenoid valves by which the position of the inner cylinder is controlled to have an open state to allow the liquid to be supplied and a closed state to prevent the liquid from being supplied. In this case, open/close driving of the opening and closing valves 387m may be controlled by a preset algorithm of the controller 390. The opening and closing valves 387m may be such that only one of the opening and closing valves 387m is set to an open state when the opening and closing driving is controlled by the controller 390, and the remaining opening and closing valves 387m are set to a closed state so that liquid is discharged only at one of the discharge positions d1.

The controller 390 controls the rotating unit 387d to rotate the discharge head 387b. Thus, the controller 390 may adjust the discharge position of the nozzle 387a by rotating the discharge head 387b.

Further, the controller 390 may control the moving unit 387f to move the discharge head 387b. Thus, the controller 390 may move the discharge head 387b to adjust the discharge position of the nozzle 387a.

Further, the controller 390 may control the tilting unit 387g to adjust the tilting angle of the discharge head 387b. Thus, the controller 390 may adjust the discharge angle of the nozzle 387a by adjusting the angle of the discharge head 387b.

In addition, the controller 390 may control the opening and closing driving of the opening and closing valve 387m. Thus, the controller 390 may control the discharge of the cleaning solution for each of the nozzles 387a.

Hereinafter, a substrate treating method using the substrate treating apparatus according to one exemplary embodiment of the present invention as described above will be described.

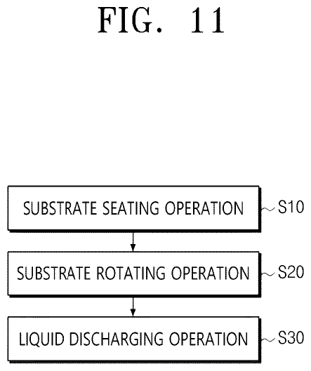

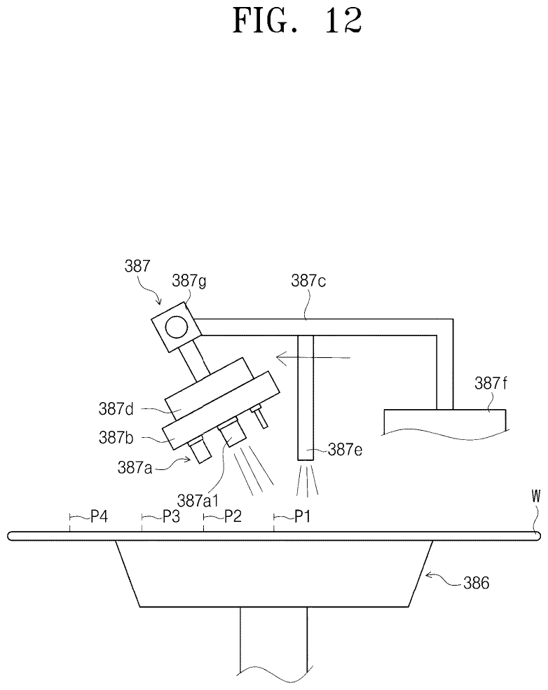

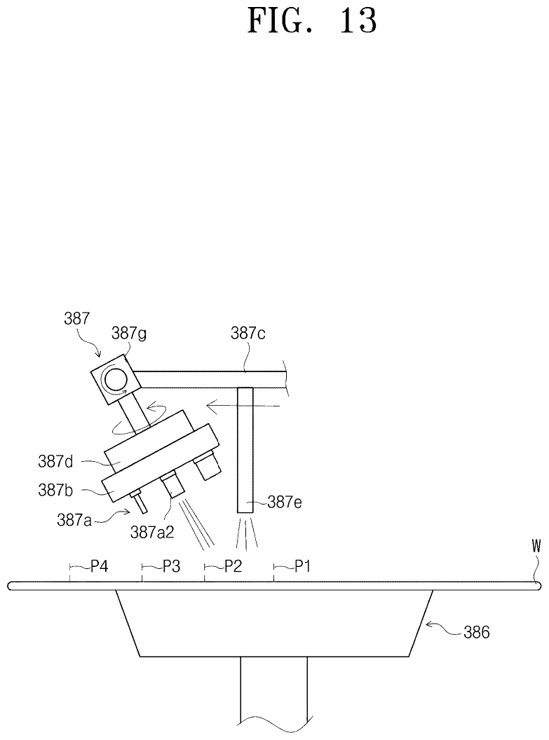

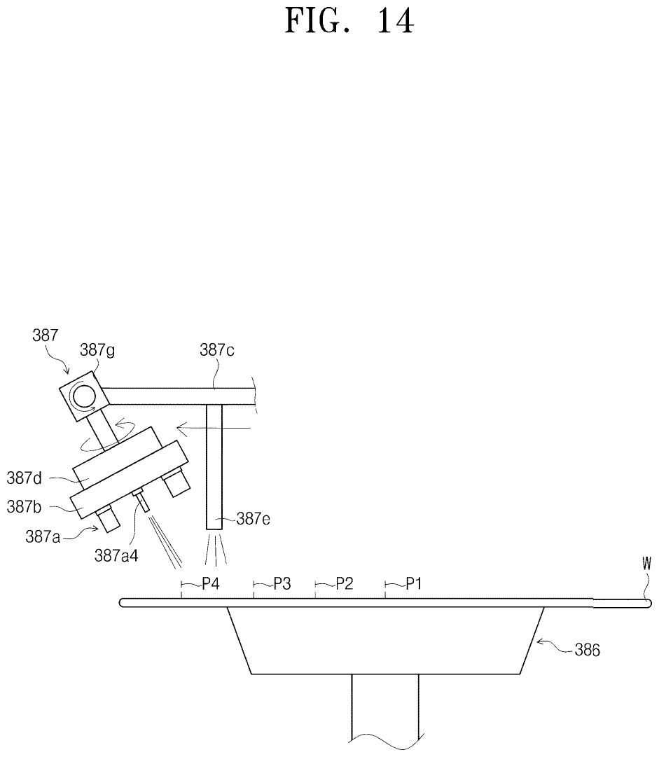

FIG. 11 is a flowchart of a substrate treating method according to an exemplary embodiment of the present invention. FIGS. 12 to 14 are driving diagrams of the substrate treating apparatus according to the substrate treating method according to the exemplary embodiment of the present invention.

Referring further to FIG. 11, a substrate treating method according to an exemplary embodiment of the present invention includes a substrate seating operation S10, a substrate rotating operation S20, and a liquid discharging operation S30.

The substrate seating operation S10 is an operation of seating the substrate W onto the support unit 386. In one example, the substrate seating operation S10 may include transferring, by the main transfer robot, the baked substrate W after exposure to the liquid treatment chamber to seat the substrate W onto the support unit 386. However, in the present invention, the substrate seating operation S10 is not limited to seating the baked substrate W onto the support unit 386, and the substrate seating operation S10 may also be performed in various liquid treatment processes, such as an etching process, a cleaning process, and a drying process.

The substrate rotating operation S20 is an operation of rotating the substrate W seated on the support unit 386. In this case, the support unit 386 may be rotated by a spindle motor to rotate the substrate W.

The liquid discharging operation S30 may discharge the cleaning solution along a straight or arc trajectory on the top surface of the substrate W while moving the nozzle 387a in one direction, but may cause the cleaning solution to be discharged from the nozzle 387a with a larger inner diameter of the outlet near the center of the substrate W, and may cause the cleaning solution to be discharged from the nozzle 387a with a smaller inner diameter of the outlet near the edge of the substrate W. In this case, the tilting unit 387g may tilt the discharge head 387b to change the discharge angle of the cleaning solution, so that the cleaning solution is discharged toward the direction in which the drying gas is discharged, thereby improving the cleaning efficiency.

In more detail, as illustrated in FIGS. 12 to 14, in the liquid discharging operation S30, when it is assumed that the center of the substrate W is a first position P1, and the positions spaced apart by a certain distance from the center of the substrate W to the edge are, in order of distance, a second position P2, a third position P3, and a fourth position P4, the controller 390 controls the moving unit 387f to move the discharge head 387b from the center of the substrate W to the edge of the substrate W such that the center direction of the discharge head 387b moves from the first position P1 to the fourth position P4. The sequential operation will be described. As illustrated in FIGS. 12 to 14, when the center of the discharge head 387b is facing the first position P1, the first nozzle 387a, which has the largest inner diameter of the outlet among the nozzles 387a, may discharge the cleaning solution and the remaining nozzles may stop the discharge of the cleaning solution. Next, the controller 390 may rotate the discharge head 387b to discharge a cleaning solution only from the second nozzle 387a2 when the center of the discharge head 387b is moved to face the second position P2. Further, the controller 390 may rotate the discharge head 387b to discharge a cleaning solution only from the third nozzle 387a3 when the center of the discharge head 387b is moved to face the third position P3, and the discharge head 387b may rotate the discharge head 387b to discharge a cleaning solution only from the fourth nozzle 387a4 when the center of the discharge head 387b is moved to face the fourth position P4.

As such, in the liquid discharging operation S30, the controller 390 may control the moving unit 387f to move the discharge head 387b from the center of the substrate W toward the edge of the substrate W, such that the cleaning solution is discharged from the nozzle 387a having a smaller inner diameter towards the edge of the substrate W. Thus, near the edge of the substrate W where the linear velocity is fast, the nozzle 387a having a relatively small outlet discharges the liquid at a fast flow rate to prevent scattering of the liquid, and near the center of the substrate W where the linear velocity is slow, the nozzle 387a having a relatively large outlet discharges the liquid at a slow flow rate to prevent scattering.

Furthermore, in the liquid discharging operation S30, the discharge position d1 of each of the plurality of nozzles 387a is changed by rotating the discharge head 387b, so that the discharge position d1 may be set very easily by only controlling the rotation of the discharge head 387b.

Furthermore, in the liquid discharging operation S30, when the cleaning solution is discharged from the nozzle 387a, drying gas is discharged from the drying gas nozzle onto the substrate W, so that film residue or particles may be removed more efficiently.

Further, in the liquid discharging operation S30, only one of the nozzles 387a may be disposed at the discharge position d1 and controlled to discharge a liquid by the control drive of the opening and closing valve 387m, while the remaining nozzles 387a may be controlled not to discharge the liquid. Thus, since the liquid is not discharged from multiple directions, but is discharged only from one nozzle 387a, the uneven spread of the liquid across the substrate W may be prevented, resulting in a uniform throughput rate across the entire surface of the substrate W.

Further, in the liquid discharging operation S30, the discharge angle of the liquid may be adjusted by adjusting the angle of the nozzle 387a such that the direction of discharging the cleaning solution from at least one of the plurality of nozzles 387a faces in a direction different from the other nozzles 387a. The discharge angle of the liquid may be adjusted by the discharge direction changer 387h, as illustrated in FIG. 15. Thus, the nozzle 387a may change the discharge direction of the liquid from the center to the edge of the substrate W by the discharge direction changer 387h. In particular, the discharge direction changer 387h may change the discharge direction so that the cleaning solution is discharged from a position where drying gas is discharged onto the substrate W.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A substrate treating apparatus for treating a substrate, the substrate treating apparatus comprising:
a cup for providing a treatment space;
a support unit provided to support a substrate in the treatment space;
a cleaning solution supply unit for supplying a cleaning solution to the substrate supported on the support unit; and
a controller for controlling the support unit and the cleaning solution supply unit,
wherein the cleaning solution supply unit includes:
a support arm;
a discharge head provided with a plurality of nozzles having outlets of different sizes;
a rotating unit for rotating the discharge head; and
a moving unit for moving the discharge head between a center region of the substrate and an edge region of the substrate, and
the controller causes the cleaning solution to be discharged while moving the discharge head between a center region of the substrate and an edge region of the substrate, and rotates the rotating unit such that, upon movement of the discharge head, nozzles having smaller inner diameters of the outlet are placed from the center region of the substrate to the edge region.

2. The substrate treating apparatus of claim 1, wherein the cleaning solution supply unit further includes a connecting rod coupling the discharge head to the support arm, and
the rotating unit rotates the discharge head about a center axis of the connecting rod.

3. The substrate treating apparatus of claim 1, wherein the plurality of nozzles is arranged in a direction surrounding a center of the discharge head.

4. The substrate treating apparatus of claim 3, wherein the plurality of nozzles is disposed at equal distances from each other from the center of the discharge head.

5. The substrate treating apparatus of claim 4, wherein the plurality of nozzles is arranged such that the size of the outlet increases progressively in a direction of rotation in one direction relative to the center of the discharge head.

6. The substrate treating apparatus of claim 1, wherein the cleaning solution supply unit further includes a drying gas nozzle coupled to the support arm and discharging drying gas onto the substrate.

7. The substrate treating apparatus of claim 6, wherein the cleaning solution supply unit further includes: a tilting unit for tilting the discharge head such that an angle of discharge of the cleaning solution is downwardly directed toward a deposit point of drying gas discharged from the drying gas nozzle.

8. The substrate treating apparatus of claim 7, wherein said controller controls said tilting unit such that a tilting angle of said discharge head varies according to the inner diameter of said nozzle.

9. The substrate treating apparatus of claim 1, wherein the cleaning solution supply unit further includes a discharge direction changer, which is coupled to at least one of the plurality of nozzles and changes the direction of discharging the cleaning solution to face a direction different from the other plurality of nozzles.

10. The substrate treating apparatus of claim 1, wherein the cleaning solution supply unit further includes:
a liquid supply line for receiving the cleaning solution from a cleaning solution supply source;
a plurality of branch lines having one end connected to the liquid supply line and the other end connected to each of the plurality of nozzles; and
an opening and closing valve installed in each of the branch lines and allowing or blocking flow of the cleaning solution into the branch lines.

11. The substrate treating apparatus of claim 10, wherein the branch line has at least a portion made of a soft material.

12. (canceled)

13. (canceled)

14. (canceled)

15. (canceled)

16. (canceled)

17. (canceled)

18. (canceled)

19. (canceled)

20. An apparatus for treating a substrate, the apparatus comprising:
a cup for providing a treatment space;
a support unit provided to support a substrate in the treatment space;
a cleaning solution supply unit for supplying a cleaning solution to the substrate supported on the support unit; and
a controller for controlling the support unit and the cleaning solution supply unit,
wherein the cleaning solution supply unit further includes:
a discharge head provided with a plurality of nozzles having outlets with different sizes;
a rotating unit for rotating the discharge head about a center axis of a connecting rod; and
a moving unit for moving the discharge head between a center region of the substrate and an edge region of the substrate,
the plurality of nozzles is arranged in a direction surrounding a center of the discharge head,
the plurality of nozzles is disposed at equal distances from each other from the center of the discharge head, and
the controller controls the cleaning solution supply unit to discharge the cleaning solution in a moving line during movement of the discharge head, wherein the controller controls the cleaning solution to be supplied from one nozzle selected from the plurality of nozzles, and the controller controls the cleaning solution supply unit to change a nozzle discharging the cleaning solution among the plurality of nozzles during the movement of the discharge head.
